(19) United States
(12) Patent Application Publication
(10) Pub. No.: US 2009/0140233 A1
(43) Pub. Date: Jun. 4, 2009

(54) NONVOLATILE SEMICONDUCTOR MEMORY DEVICE

(76) Inventors: Masaharu KINOSHITA, Kokubunji (JP); Motoyasu Terao, Hinode (JP); Hideyuki Matsuoka, Nishitokyo (JP); Yoshitaka Sasago, Tachikawa (JP); Yoshinobu Kimura, Tokyo (JP); Akio Shima, Hino (JP); Mitsuharu Tai, Kokubunji (JP); Norikatsu Takaura, Tokyo (JP)

Correspondence Address: MATTINGLY & MALUR, P.C., 1800 DIAGONAL ROAD, SUITE 370, ALEXANDRIA, VA, 22314, US

(21) Appl. No.: 12/268,118

(22) Filed: Nov. 10, 2008

(30) Foreign Application Priority Data
Nov. 12, 2007 (JP) 2007-292723

(51) Int. Cl. H01L 45/00

(52) U.S. Cl. 257/4; 257/E45.002

(57) ABSTRACT

A nonvolatile semiconductor memory device having a large storage capacity and stabilized rewriting conditions in which a memory cell includes a nonvolatile recording material layer, a selector element and a semiconductor layer provided between the nonvolatile recording material layer and the selector element and having a thickness ranging from 5 to 200 nm.

### INCORPORATION BY REFERENCE

The present application claims priority from Japanese application JP 2007-292723 filed on Nov. 12, 2007, the content of which is hereby incorporated by reference into this application.

### BACKGROUND OF THE INVENTION

The present invention relates to electrically rewritable phase change memory devices which store, in a non-volatile manner, resistances variably determined through phase changes between a crystalline state and an amorphous state of a metal compound.

There are known some nonvolatile memory devices utilizing a metal compound which is brought into a crystalline or amorphous state representative of information to be stored. Generally, a tellurium compound is used as a storage material. The principle of information storage by making use of differences in reflectances of the compound is widely employed in the optical information storage media such as DVDs (Digital Versatile Disks).

Recently, it has been proposed to apply this principle to electrical information storage media. In this proposal, contrary to the optical approach, differences between the resistances in its amorphous and crystalline states, namely, a high resistance in the amorphous state and a low resistance of the material in the crystalline state are detected in the form of current changes or voltage changes.

This electrical information storage media is called a phase change memory having a basic memory cell structure which includes a combination of a phase change resistance element and a selector element. The phase change memory has a phase change resistance element constituted by a nonvolatile recording material layer in which the phase change resistance element is brought into its crystalline state or its amorphous state by Joule heat generated by causing an electric current to flow into the phase change resistance element. The phase change memory retains the crystalline state of or the amorphous state of the nonvolatile recording material layer to thereby store or hold information.

In rewriting the memory, to obtain an electrical high resistance in the amorphous state, a large current is caused to flow in the variable resistance material, which is a nonvolatile recording material, to heat it to a temperature not lower than its melting point and thereafter it is cooled rapidly, while to obtain an electrical low resistance in the crystalline state, a limited current is caused to flow in it to heat it to a crystallization temperature lower than the melting point. In general, resistance changes of the nonvolatile recording material layer owing to the phase change is in the range of two to three orders of magnitudes. Thus, the phase change memory provides readout signals of magnitudes significantly different depending on which of the crystalline and amorphous states is acquired, thereby facilitating a sense operation.

### SUMMARY OF THE INVENTION

In the conventional phase change memory, in order to rewrite it, the nonvolatile recording material layer is heated to a very high temperature to accomplish a phase change from the crystalline state to the amorphous state or vice versa. Therefore, as the number of times of the rewriting operation is larger, more atoms constituting a film adjacent to the nonvolatile recording material layer diffuse from that adjacent film into the nonvolatile recording material layer, with a disadvantageous result that conditions for the rewriting are changed.

With the conventional art such as disclosed, for example, in US 2006/0203541A1, a metal film is disposed between a nonvolatile recording material layer and a selector element so as to provide an electrically ohmic contact therebetween. In this structure, however, diffusion of metal elements from the metal film into the nonvolatile recording material layer may take place, which may lead to changes in conditions for rewriting.

In U.S. Pat. No. 6,426,891B1, an electrically conductive adiabatic film is disposed between a nonvolatile recording material layer and a selector element for the purpose of preventing diffusion of heat from the nonvolatile recording material layer generated at a rewriting operation. In this structure, however, a rapid cooling operation necessary for bringing the nonvolatile recording material layer into the amorphous state may be difficult.

An object of the present invention is to provide a phase change memory device free from diffusion of atoms from the layer adjacent to the nonvolatile recording material layer, in which atoms contained in the layer adjacent to the nonvolatile recording material layer are such that, even if diffusion of atoms occurred, atoms having diffused would not influence the rewriting conditions.

Another object of the present invention is to provide a phase change memory device in which a rapid cooling for realizing the amorphous state is facilitated to keep stabilized conditions for rewriting.

According to one aspect of the present invention, a nonvolatile semiconductor memory device includes a first electrode, a second electrode, a nonvolatile recording material layer and a selector element both formed between the first and second electrodes, and a semiconductor layer formed between the nonvolatile recording material layer and the selector element, the semiconductor layer containing an element identical with that contained in the nonvolatile recording material layer.

Hereinafter, in this specification, a semiconductor layer containing an element identical with that contained in a nonvolatile recording material layer will be referred to as “a semiconductor layer”, for simplicity sake.

In some of the embodiments of the present invention, phase change memory devices enjoy stable conditions for rewriting. For example, with the nonvolatile phase change memory devices, it becomes possible to rewrite 10⁹ times or more with a rewrite time of 50 nsec or shorter.

Other objects, features and advantages of the invention will become apparent from the following description of the embodiments of the invention taken in conjunction with the accompanying drawings.

### BRIEF DESCRIPTION OF THE DRAWINGS

FIG. 1 is a cross-sectional view of a major portion of a memory cell in a nonvolatile semiconductor memory device according to Embodiment 1 of the present invention.

FIG. 2 is a cross-sectional view of a major portion of a memory cell in a nonvolatile semiconductor memory device according to Embodiment 2 of the present invention.

FIG. 3 is a cross-sectional view of a major portion of a memory cell in a nonvolatile semiconductor memory device according to Embodiment 3 of the present invention.

FIG. 4 is a cross-sectional view of a major portion of a memory cell in a nonvolatile semiconductor memory device according to Embodiment 4 of the present invention.

FIG. 5 is a perspective view of the semiconductor memory device according to Embodiment 1 which is at a manufacturing step.

FIG. 6 is a diagram showing a positional relationship among a silicon substrate, a peripheral circuit portion and a memory matrix portion.

FIG. 7 is a diagram showing another positional relationship among a silicon substrate, a peripheral circuit portion and a memory matrix portion.

FIG. 8 is a diagram showing still another positional relationship among a silicon substrate, a peripheral circuit portion and a memory matrix portion.

FIG. 9 is a perspective view of the semiconductor memory device at a manufacturing step subsequent to the step shown in FIG. 5.

FIG. 10 is a perspective view of the semiconductor memory device at a manufacturing step subsequent to the step shown in FIG. 9.

FIG. 11 is a perspective view of the semiconductor memory device at a manufacturing step subsequent to the step shown in FIG. 10.

FIG. 12 is a perspective view of the semiconductor memory device at a manufacturing step subsequent to the step shown in FIG. 11.

FIG. 13 is a perspective view of the semiconductor memory device at a manufacturing step subsequent to the step shown in FIG. 12.

FIG. 14 is a perspective view of the semiconductor memory device at a manufacturing step subsequent to the step shown in FIG. 13.

FIG. 15 is a perspective view of the semiconductor memory device at a manufacturing step subsequent to the step shown in FIG. 14.

FIG. 16 is a perspective view of the semiconductor memory device at a manufacturing step subsequent to the step shown in FIG. 15.

FIG. 17 is a perspective view of the semiconductor memory device at a manufacturing step subsequent to the step shown in FIG. 16.

FIG. 18 is a perspective view of the semiconductor memory device at a manufacturing step subsequent to the step shown in FIG. 17.

FIG. 19 is a plan view of the structure shown in FIG. 18.

FIG. 20 is a circuit diagram of a major portion of a memory matrix in a semiconductor device in one embodiment of the present invention.

FIG. 21 is a perspective view of the semiconductor memory device according to a modification of Embodiment 1.

FIG. 22 is a perspective view of the semiconductor memory device according to Embodiment 2 which is at a manufacturing step.

FIG. 23 is a perspective view of the semiconductor memory device at a manufacturing step subsequent to the step shown in FIG. 22.

FIG. 24 is a perspective view of the semiconductor memory device at a manufacturing step subsequent to the step shown in FIG. 23.

FIG. 25 is a perspective view of the semiconductor memory device at a manufacturing step subsequent to the step shown in FIG. 24.

FIG. 26 is a perspective view of the semiconductor memory device at a manufacturing step subsequent to the step shown in FIG. 25.

FIG. 27 is a perspective view of the semiconductor memory device at a manufacturing step subsequent to the step shown in FIG. 26.

FIG. 28 is a diagram showing optical constants of Si—Ge compounds.

FIG. 29 is a perspective view of the semiconductor memory device at a manufacturing step subsequent to the step shown in FIG. 27.

FIG. 30 is a plan view of the structure shown in FIG. 29.

FIG. 31 is a perspective view of the semiconductor memory device according to Embodiment 3.

FIG. 32 is a perspective view of the semiconductor memory device according to Embodiment 4.

### DETAILED DESCRIPTION OF THE EMBODIMENTS

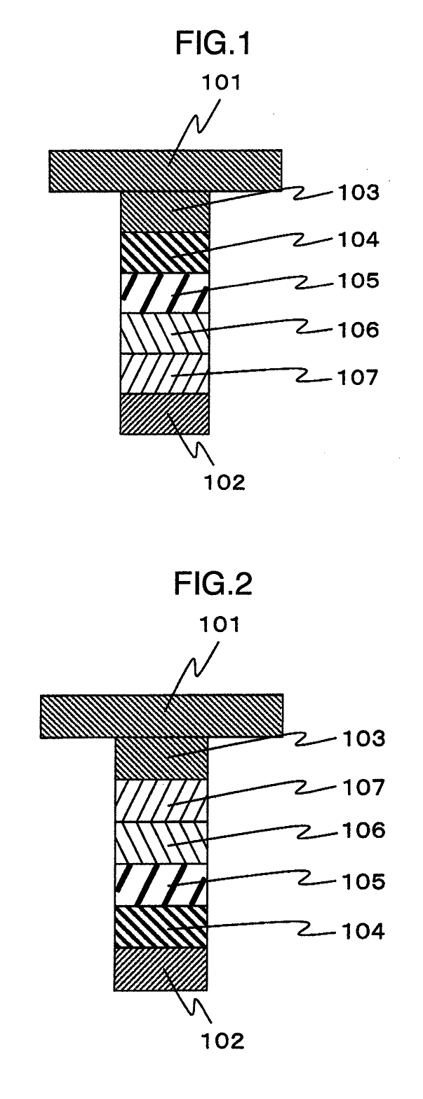

Memory cells in a nonvolatile memory in some embodiments of the present invention will be described with reference to FIGS. 1 to 4. The memory cells will be described as having a so-called pillar structure in which a nonvolatile recording material layer and a selector element are electrically connected to each other in the same stack without a plug therebetween. Thus, this pillar structure is unlike a structure in which a nonvolatile recording material layer and a selector element are in different stacks and are electrically connected with each other through a plug.

Further, it is assumed here that the selector element is a pn polycrystalline silicon diode by way of example. Thus, FIGS. 1 to 4 show a first polycrystalline layer and a second polycrystalline layer forming a pn junction. However, the selector element may be in a structure having another junction such as an np junction, a pin junction or an nip junction. Alternately, the selector element in a memory cell may have a Schottky junction between a metal connection conductor layer and a polycrystalline silicon layer (hereafter, referred to as “a poly-silicon layer”). The nonvolatile recording material layer is assumed to be made of Ge₂Sb₂Te₅ by way of example, but it may be made of a material composed of at least one of the chalcogen elements (S, Se and Te) to provide similar functional effects.

Structures of multiple layers in different lamination orders and preferable thickness of the semiconductor layer in the respective embodiments will now be described.

FIG. 1 shows a major portion of a memory cell of a structure in Embodiment 1, in which there are formed, on a first metal connection conductor layer 102, a first poly-silicon layer 107, a second poly-silicon layer 106, a semiconductor layer 105, a nonvolatile recording material layer 104, a second metal connection conductor layer 103 and a third metal connection conductor layer 101, in the described order.

The nonvolatile recording material layer 104 is formed on the semiconductor layer 105, the layer 104 being over the first and second poly-silicon layers 107 and 106. In this way, since the semiconductor layer 105 is formed between a pn poly-silicon (polycrystalline silicon) diode constituted by the first and second poly-silicon layers 107 and 106 and the nonvolatile recording material layer 104, it is possible to suppress diffusion into the nonvolatile recording material layer 104 of dopant atoms contained as an impurity in the pn poly-silicon diode due to heat generated at a rewriting operation.

In this connection, the semiconductor layer 105 should not be too thick and should not be too thin to carry out its intended function. If it is too thick, it will have a too large resistance, though electrically conductive, with the resistance being temperature-dependent to make the temperature margin of the resistance of the nonvolatile recording material layer 104 insufficient. If it is too thin, it will not serve to prevent degradation of the characteristics of the selector element due to the repetitive temperature rise in the nonvolatile recording material layer 104 at a storing/rewriting operation.

The relation between the thickness and the ratio between resistances in the low resistance and high resistance states, at high temperatures, of the semiconductor layer 105 is as follows: when the layer 105 is 160 nm thick, the ratio between resistances in the low resistance and the high resistance states is 1:20; when the layer 105 is 200 nm thick, the above ratio is 1:10; and when the layer 105 is 240 nm thick, the above ratio is 1:5.

For the nonvolatile memory of such variable resistance type, it is required that the ratio between the resistances in the low resistance and the high resistance states should be in the extent of 10 from the viewpoint of avoidance of readout failure. Consequently, the thickness of the semiconductor layer 105 should be 200 nm or smaller.

Meanwhile, the relation between the thickness of the semiconductor layer 105 and the maximum number of times of rewriting is as follows: when the layer 105 is 3 nm, the above maximum number of times is 105; when the layer 105 is 5 nm thick, the above maximum number of times is 106; and when the layer 105 is 8 nm, the above maximum number of times is 106.

For the nonvolatile memory of a variable resistance type, it is required that the maximum number of times of rewriting should be about 10⁶ or larger. Consequently, the thickness of the semiconductor layer 105 should be 5 nm or larger.

FIG. 2 shows a major portion of a memory cell of a structure according to Embodiment 2, in which there are formed, on a first metal connection conductor layer 102, a nonvolatile recording material layer 104, a semiconductor layer 105, a second poly-silicon layer 106, a first poly-silicon layer 107, a second metal connection conductor layer 103 and a third metal connection conductor layer 101, in the described order.

The nonvolatile recording material layer 104 is formed at a level lower than the semiconductor layer 105 and the second and first poly-silicon layers 106 and 107. In this way, since the semiconductor layer 105 is formed between the pn poly-silicon diode constituted by the first and second poly-silicon layers 107 and 106 and the nonvolatile recording material layer 104, it is possible to suppress diffusion into the nonvolatile recording material layer 104 of dopant atoms in the pn poly-silicon diode contained therein as an impurity due to heat generated at the rewriting operation.

In this connection, the semiconductor layer 105 should not be too thick and should not be too thin to carry out its intended function. If it is too thick, it will have a too large resistance, though electrically conductive, with the resistance being temperature-dependent to make the temperature margin of the resistance of the nonvolatile recording material layer 104 insufficient. If it is too thin, it will not serve to prevent degradation of the characteristics of the selector element due to the repetitive temperature rise in the nonvolatile recording material layer 104 at the storing/writing operation.

Both the relationship between the thickness and the ratio between resistances in the low resistance and the high resistance states of the semiconductor layer 105 and the relation between the thickness of the semiconductor layer 105 and the maximum number of times of rewriting described in connection with the structure shown in FIG. 1 are applicable to the structure shown in FIG. 2,

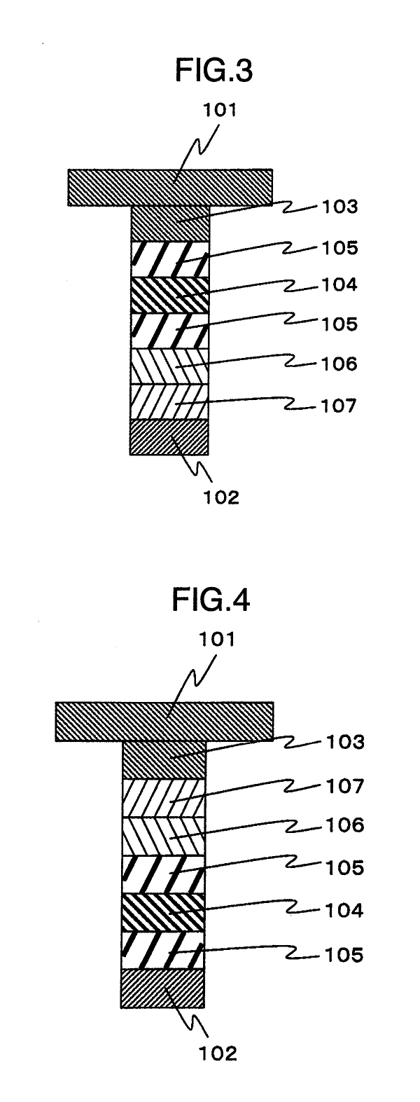

FIG. 3 shows a major portion of a memory cell of a structure according to Embodiment 3, in which there are formed, on a first metal connection conductor layer 102, a first poly-silicon layer 107, a second poly-silicon layer 106, a semiconductor layer 105, a nonvolatile recording material layer 104, another semiconductor layer 105, a second metal connection conductor layer 103 and a third metal connection conductor layer 101, in the described order. Namely, in the structure shown in FIG. 3, a second semiconductor layer 105 is additionally formed between the first semiconductor layer 105 and the second metal connection conductor layer 103, as compared to the structure shown in FIG. 1

By this structure, in addition to the functional effects described in connection with the structure shown in FIG. 1, it is possible to suppress diffusion into the nonvolatile recording material layer 104 of metal atoms in the second metal connection conductor layer 103 to suppress changes of the rewriting conditions which may be caused by such metal atoms. Furthermore, the additional semiconductor layer 105 serves to suppress degradation of the second metal connection conductor layer 103 stemming from heat cycles, which leads to an increase of the maximum number of times of rewriting at least to five times as large as that without the additional semiconductor layer 105.

FIG. 4 shows a major portion of a memory cell of a structure according to Embodiment 4, in which there are formed, on a first metal connection conductor layer 102, a semiconductor layer 105, a nonvolatile recording material layer 104, another semiconductor layer 105, a second poly-silicon layer 106, a first poly-silicon layer 107, a second metal connection conductor layer 103 and a third metal connection conductor layer 101, in the described order. Namely, in the structure shown in FIG. 4, a second semiconductor layer 105 is additionally formed between the first semiconductor layer 105 and the first metal connection conductor layer 102, as compared to the structure shown in FIG. 2.

By this structure, in addition to the functional effects described in connection with the structure shown in FIG. 2, it is possible to suppress diffusion into the nonvolatile recording material layer 104 of metal atoms in the first metal connection conductor layer 102 to suppress changes of the rewriting conditions which may be caused by such metal atoms. Furthermore, the additional semiconductor layer 105 serves to suppress degradation of the first metal connection conductor layer 102 stemming from heat cycles, which leads to an increase of the maximum number of times of rewriting at least to five times as large as that without the additional semiconductor layer 105.

Both the relationship between the thickness and the maximum number of times of rewriting and the relation between the total thickness of the two semiconductor layers 105 and the resistance ratio described in connection with the structure shown in FIG. 1 are applicable to the structures shown in FIGS. 3 and 4.

### Embodiment 1

A method of manufacturing a memory cell of a nonvolatile memory will be described in detail with reference to the accompanying drawings. Throughout the drawings, members having similar functions are denoted by the same reference symbols and description of the similar members will not be repeated.

In the description of the following embodiments, generally, explanation of similar or same parts will not be repeated except when it is particularly necessary. With respect to the drawings referred to in connection with the described embodiments, cross-sectional views may not be provided with hatching for clarity of illustration, and plan views may be provided with hatching for clarity of illustration.

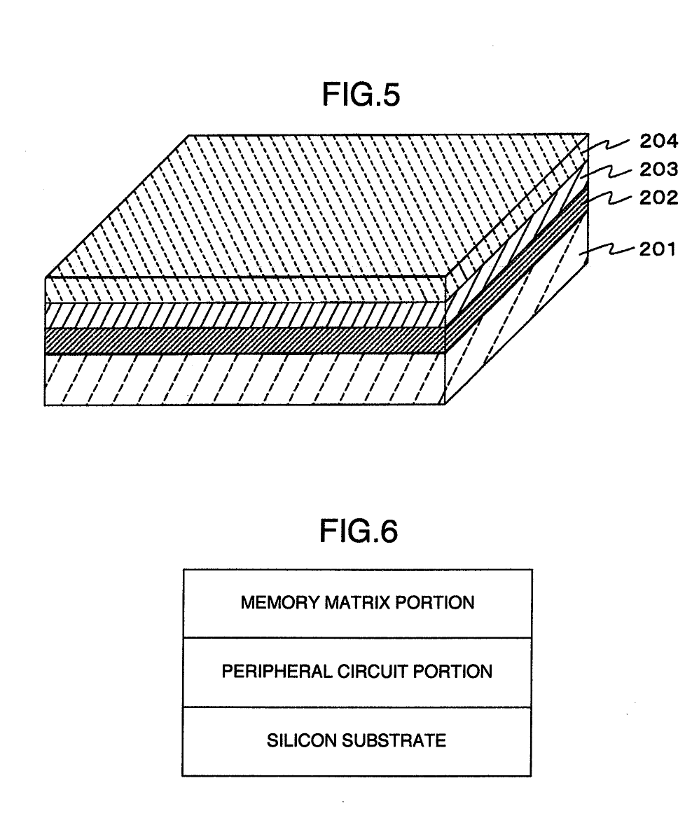

In this embodiment, as shown in FIG. 5, a memory cell is formed on a semiconductor substrate 201. The semiconductor substrate 201 is not only for a nonvolatile memory but also for a peripheral circuit to be formed therein for operating a memory matrix of the nonvolatile memory. The peripheral circuit may be fabricated by the use of the conventional CMOS technology.

FIGS. 6 to 8 show various positional relationships among a silicon substrate, a memory matrix portion and a peripheral circuit. These drawings are schematic cross-sectional views taken in a direction perpendicular to a device fabrication surface of the silicon substrate being a semiconductor substrate. In this embodiment, the manufacturing process is described on an assumption that a memory matrix portion is fabricated on a peripheral circuit as shown in FIG. 6, by way of example. Thus, on the silicon substrate, a peripheral circuit is formed in a first stack level and a memory matrix portion is formed in a second stack level, providing a multi-stack structure.

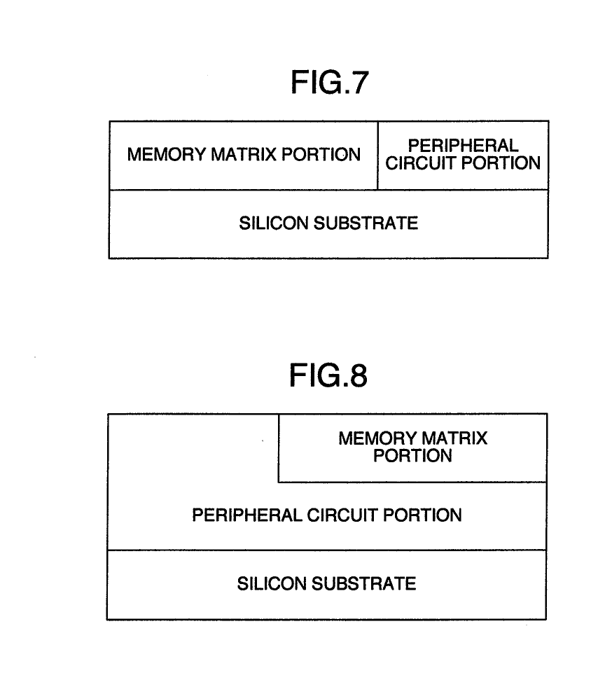

The positional relationship between the memory matrix and the peripheral circuit in a multi-stack structure may be such as shown in FIG. 7 in which they are in the same stack level or may be such as shown in FIG. 8 in which the peripheral circuit portion is partly in the same stack level as the memory matrix portion and is partly in the stack level underlying the memory matrix portion. Furthermore, in the structures shown in FIGS. 6 and 8, the memory matrix portion is partly or wholly in the second stack level, but it may be in a third or fourth stack level. Namely, FIGS. 6 and 8 are intended to show examples of structures in which a memory matrix portion is at least at a layer level higher than that of a peripheral circuit portion.

Referring back to FIG. 5 showing a structure at a step in which, on a semiconductor substrate 201, a first metal connection conductor layer 202, a first poly-silicon layer 203 and a second amorphous silicon layer 204 are formed, in the described order. The first metal connection conductor layer 202 is made of tungsten and is formed by sputtering. More preferably, the layer 202 should be made of, for example, aluminum or copper, because these materials have resistivities lower than that of tungsten to exhibit smaller voltage drops which will permit higher readout current. Further, an intermetallic compound such as TiN may be formed between the first metal connection conductor layer 202 and the semiconductor substrate 201 to strengthen their adhesion to each other.

The first poly-silicon layer 203 is formed in the following manner: an amorphous silicon containing boron, gallium or indium is deposited by LP-CVD (Low Pressure Chemical Vapor Deposition), is crystallized by RTA (Rapid Thermal Annealing) and the dopants are activated. The first poly-silicon layer 203 is 50 to 250 nm thick. When the first metal connection conductor layer 202 is made of tungsten, the material for forming the first poly-silicon layer 203 should preferably be an amorphous silicon containing boron rather than that containing gallium or indium, because thereby tungsten silicide is less likely to be formed. Moreover, an intermetallic compound such as TiN may be deposited between the first poly-silicon layer 203 and the first metal connection conductor layer 202 to prevent the tungsten from directly contacting the amorphous silicon to cause reactions therebetween to produce a tungsten silicide.

The second amorphous silicon layer 204 is obtained by depositing an amorphous silicon containing phosphorus or arsenic by LP-CVD. The second amorphous silicon layer 204 is 50 to 250 nm thick.

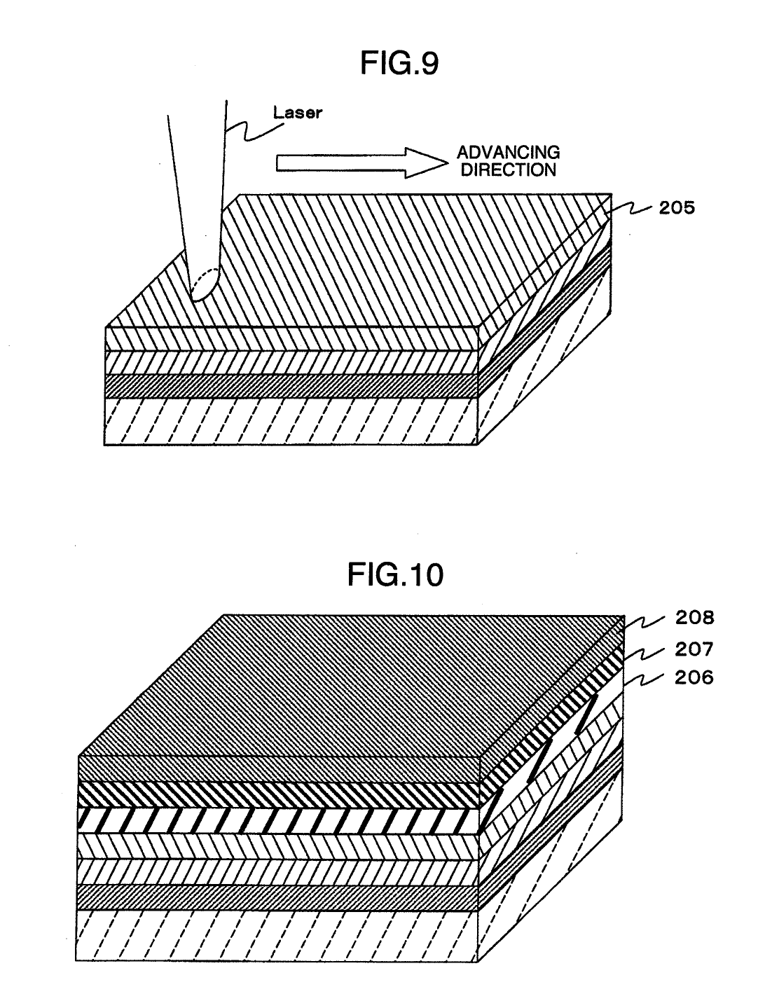

FIG. 9 illustrates a step of laser-annealing of the second amorphous silicon layer 204 deposited as shown in FIG. 5. By the laser-annealing, the amorphous silicon layer 204 is crystallized and the dopants are activated, thereby forming a second poly-silicon layer 205. In this embodiment, since the selector element in each memory cell is a pn diode, the first and second poly-silicon layers 203 and 205 are described as having a pn junction. However, a selector element, having another junction such as an np junction, a pin junction or a pi junction, or having a Schottky junction formed with the first metal connection conductor layer 202, may be used to constitute a memory cell.

FIG. 10 shows a structure at a step in which, on the structure shown in FIG. 9, a semiconductor layer 206, a nonvolatile recording material layer 207, a second metal connection conductor layer 208 are formed in the described order. The layers 206, 207 and 208 are deposited by sputtering.

The nonvolatile recording material layer 207 is made of Ge₂Sb₂Te₅ and is 5 to 300 nm thick. More preferably, the layer 207 should be 5 to 20 nm thick to lower its aspect ratio thereby facilitating subsequent steps of dry etching and burying insulating materials.

The semiconductor layer 206 is made of a material containing an element which constitutes the nonvolatile recording material layer 207. By using such semiconductor layer, even when diffusion of the element from the semiconductor layer 206 into the nonvolatile recording material layer 207 occurs in part in a high temperature state at the annealing step, it is possible to suppress influences on the rewriting characteristics and on the diode performance to such a degree of practically negligible. For example, even if diffusion of Ge into the Ge—Sb—Te material occurred, the memory performance would remain in a negligible degree.

The semiconductor layer 206 is made of Ge with which the nonvolatile recording material layer 207 is resistant to changes in the rewriting conditions and has a thickness of not smaller than 5 nm and not larger than 200 nm. The reasons for definition of this range of thickness is such as has been described above. It is preferable that the semiconductor layer 206 has a Ge content not smaller than 90 atomic %. The semiconductor layer 206 may be made of a Ge—Si mixture material, instead of Ge, to provide similar functional effects. Also in this case, the layer 206 should preferably have a thickness of not smaller than 5 nm and not larger than 200 nm.

Alternately, the semiconductor layer 206 may be made of a material containing Ge and another element other than Si. In this case, the Ge content should preferably be not smaller than 40 atomic %, which makes rewriting characteristics of the nonvolatile memory resistant to degradation. In other words, when the semiconductor layer 206 is made of a material other than Ge—Si mixture materials, the material of the layer 206 should contain not smaller than 40 atomic % of Ge. Alternately, the semiconductor layer 206 may be made of any one of the known various semiconductor materials. For example, InSb or GaSb may be employed.

The particularly important point with respect to the semiconductor layer is that the layer should be made of a semiconductor material containing a material which constitutes the nonvolatile recording material layer. In this connection, it is preferable that the semiconductor layer should have a thickness of not smaller than 5 nm and not larger than 200 nm.

In this embodiment, although the material of the nonvolatile recording material layer 207 is Ge₂Sb₂Te₅ by way of example, another nonvolatile recording material layer made of Ge₃Sb₂Te₆, Ge₅Sb₂Te₈ or Ge—Te may be used.

The phase change memory is based on one of the information rewriting principles. When the memory is otherwise based on the principle of the operation of a solid electrolyte memory, the nonvolatile recording material layer may be, for example, a Cu₂Se layer or a GeSe layer, and at least one of the first and second metal connection conductor layers may be made of Cu. In this connection, it is noted that the solid electrolyte memories are classified into those having a bidirectional operation mode in which writing and erasing operations require voltages in opposite directions to each other and those having a unidirectional operation mode in which writing and erasing operations require voltages in one and the same direction. Since the memory according to this embodiment includes diodes as selector elements, the unidirectional operation mode will have to be adopted.

The semiconductor layer 206 should not be too thick and should not be too thin to carry out its intended function. If it is too thick, it will have a too large resistance, though electrically conductive, with the resistance being temperature-dependent to make the temperature margin of the resistance of the nonvolatile recording material layer 207 insufficient. If it is too thin, it will not serve to prevent degradation of the characteristics of the selector element due to the repetitive temperature rise in the nonvolatile recording material layer 207 at the storing/rewriting operation. The thickness of the semiconductor layer 206 should be not smaller than 5 nm and not larger than 200 nm for the reasons mentioned above.

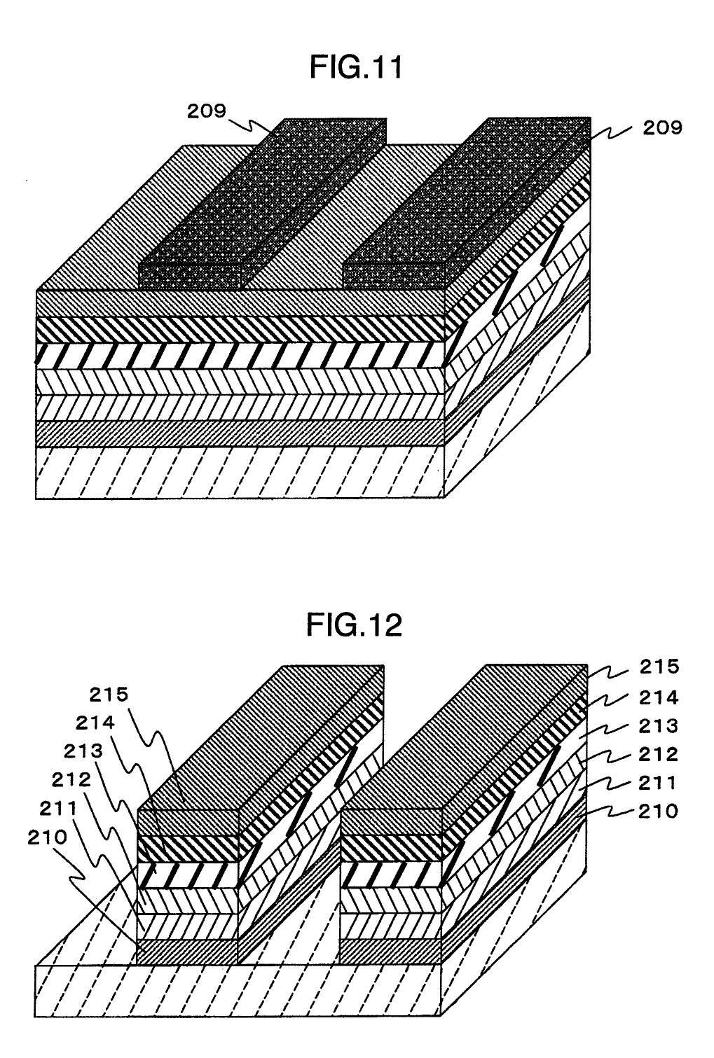

FIG. 11 shows a structure at a step in which a resist having been patterned by a known lithography technique is formed on the structure shown in FIG. 10. The pattern of the resist 209 is for word lines of a memory matrix and is longitudinally striped, extending in parallel with adjacent pattern of word lines.

FIG. 12 shows a structure at a step in which, by a known dry etching technique with the resist 209 shown in FIG. 11 used as a mask, the second metal connection conductor layer 208, the nonvolatile recording material layer 207, the semiconductor layer 206, the second poly-silicon layer 205, the first poly-silicon layer 203 and the first metal connection conductor layer 202 are etched, and the resist 209 is thereafter removed by a known technique. The pattern of the multi-layer films each consisting of the first metal connection conductor layer 210, the first poly-silicon layer 211, the second poly-silicon layer 212, the semiconductor layer 213, the nonvolatile recording material layer 214 and the second metal connection conductor layer 215 reflects the pattern of the resist 209, and is, therefore, a longitudinally striped pattern. Although the first metal connection conductor layers 210 serving as word lines in a memory matrix are electrically connected with the semiconductor substrate 201 for reading and writing the nonvolatile memory, illustration of such electrical connection is omitted.

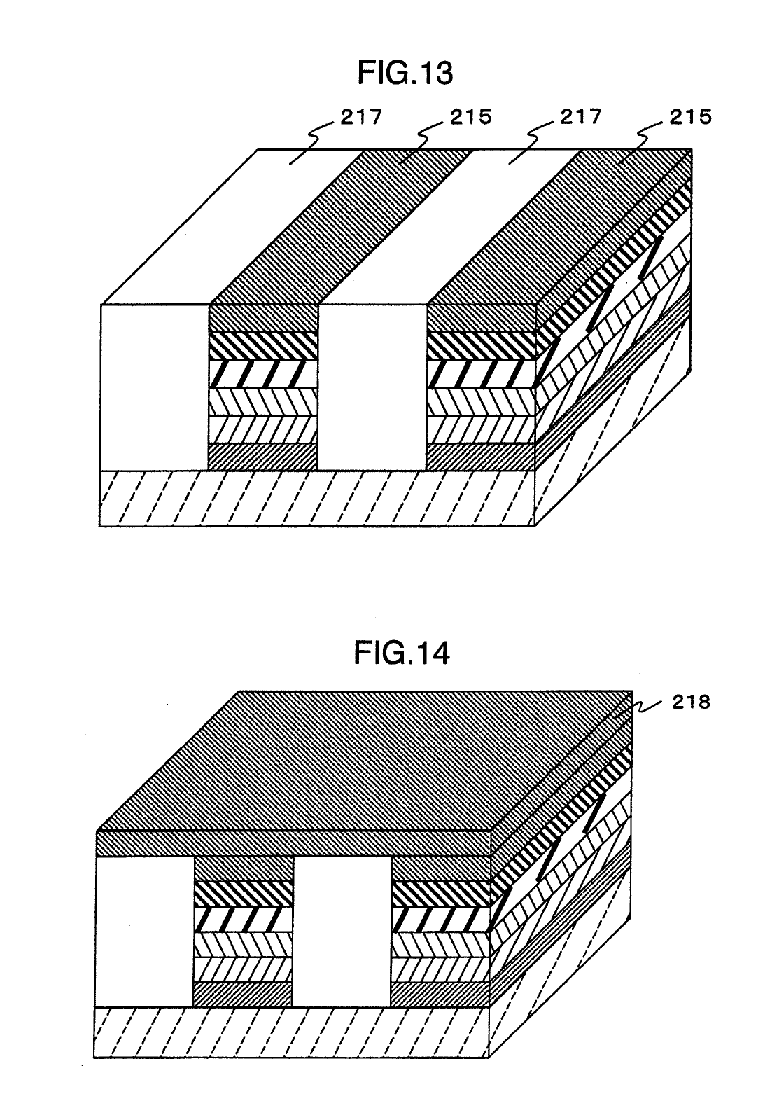

FIG. 13 shows a structure at a step in which, on the patterned structure shown in FIG. 12, an electrically insulating material is formed and is then polished by a known CMP (Chemical Mechanical Polishing) technique. The polishing is carried out to such an extent that the insulating material 217 levels with the second metal connection conductor layer 215.

FIG. 14 shows a structure at a step in which a third metal connection conductor layer 218 is formed, by sputtering, on the insulating material 217 and the second metal connection conductor layer 215 in the structure shown in FIG. 13. The third metal connection conductor layer 218 is made of tungsten, but more preferably, it may be made of aluminum or copper having a lower resistivity.

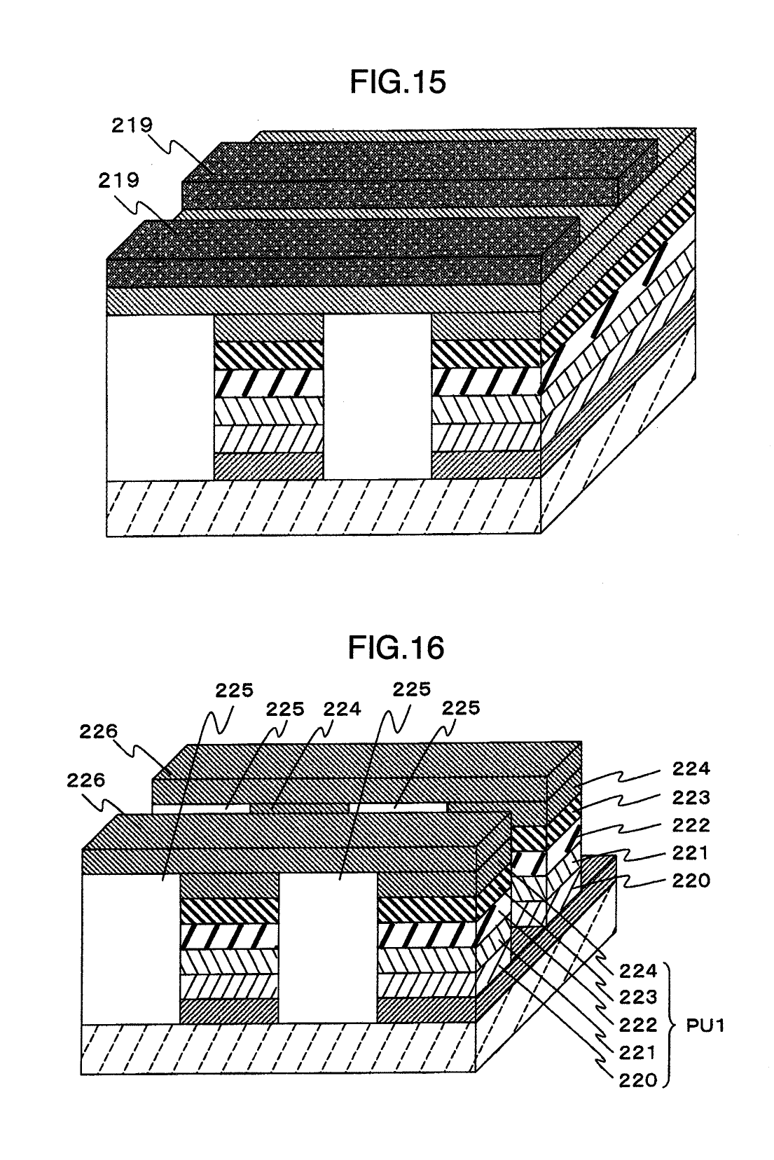

FIG. 15 shows a structure at a step in which a resist is formed on the third metal connection conductor layer 218 in the structure shown in FIG. 14 and is patterned through a known lithography technique. The pattern of the resist 219 is for bit lines of a memory matrix and is laterally striped, extending in parallel with adjacent pattern of bit lines. The pattern of the resist 219 intersect the pattern of the first metal connection conductor layers 210.

FIG. 16 shows a structure at a step in which, by a known dry etching technique with the resist 219 shown in FIG. 15 uses as a mask, the third metal connection conductor layer 218, the second metal connection conductor layer 215, the nonvolatile recording material layer 214, the semiconductor layer 213, the second poly-silicon layer 212, the first poly-silicon layer 211 and the insulating material 217 are patterned, and the resist 219 is thereafter removed by a known technique. At this time, it is necessary to leave the first metal connection conductor layers 210 as they are, the first metal connection conductor layers 210 serving as word lines in a memory matrix so that selection of memory cells is possible.

A first poly-silicon layer 220, a second poly-silicon layer 221, a semiconductor layer 222, a nonvolatile recording material layer 223 and a second metal connection conductor layer 224 constitute a multi-layer film PU1 which is pillar-shaped. Adjacent third metal connection conductor layers 226 serving as bit lines in a memory matrix are in parallel with each other and are longitudinally striped. The third metal connection conductor layers 226 are arranged so as to intersect the first metal connection conductor layers 210. Further, although the third metal connection conductor layers 226 as bit lines are electrically connected with the semiconductor substrate 201 for reading and writing the nonvolatile memory, illustration of such electrical connection is omitted.

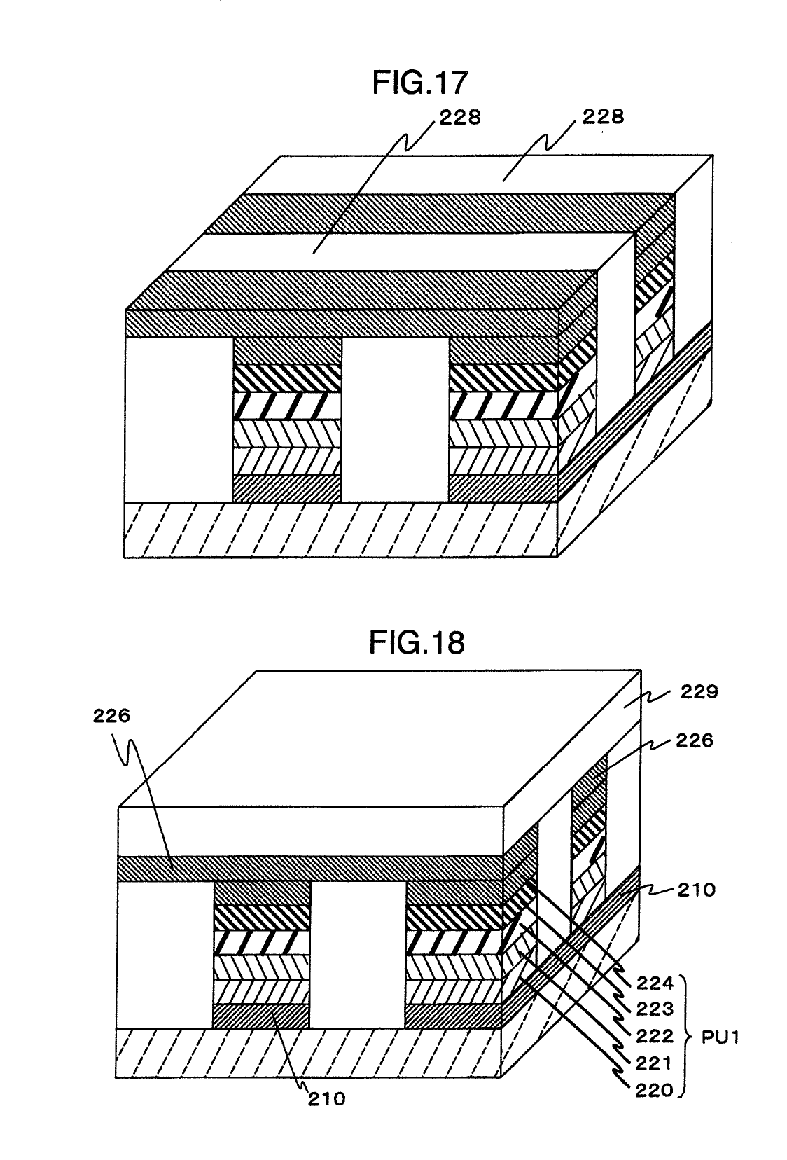

FIG. 17 shows a structure at a step in which, on the patterned structure shown in FIG. 16, an electrically insulating material is formed and is then polished by a known CMP technique. The polishing is carried out to such an extent that the insulating material 228 levels with the third metal connection conductor layer 226.

FIG. 18 shows a structure at a step in which an insulating material 229 is formed on the structure shown in FIG. 17.

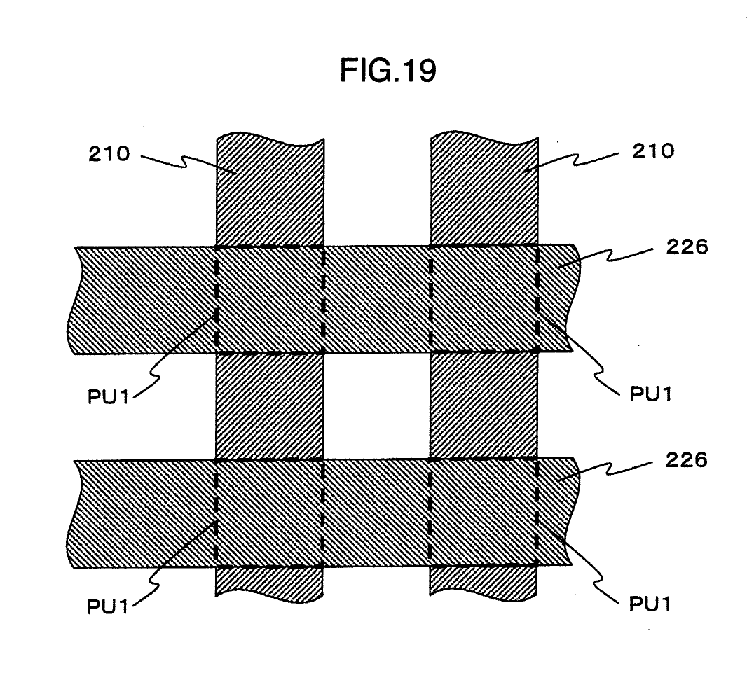

FIG. 19 is a plan view of a memory cell manufactured according to the steps described with reference to FIGS. 5 to 18. The first metal connection conductor layers 210 serving as word lines intersect the third metal connection conductor layers 226 serving as bit lines in memory cells, and the multi-layer films PU1 are arranged at the intersections.

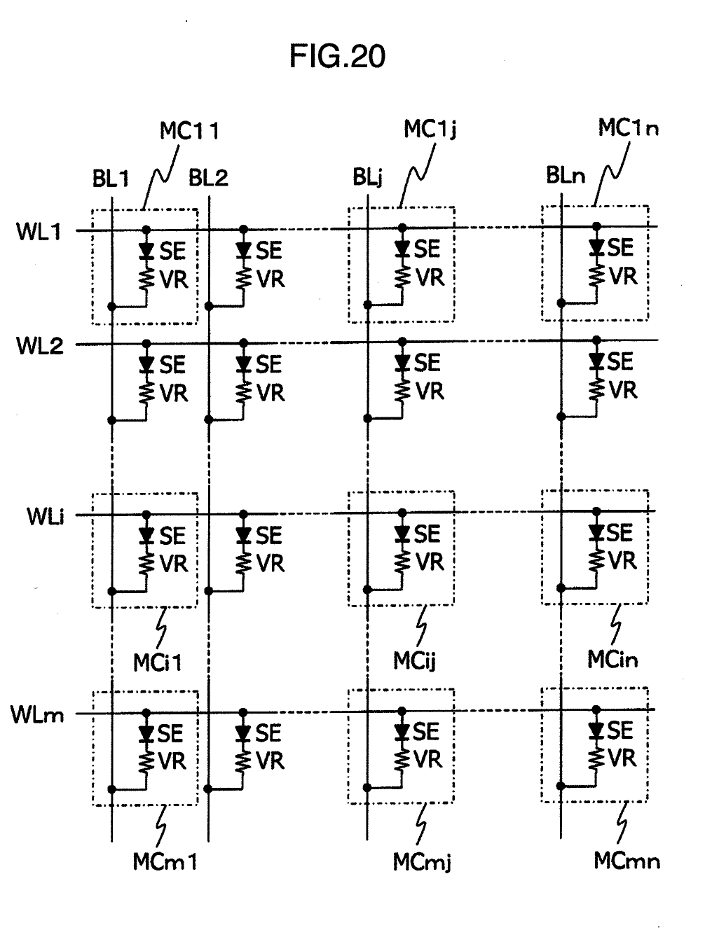

An operation mode of a memory matrix including memory cells in a nonvolatile memory according to one embodiment of the present invention will now be described with reference to FIG. 20.

In FIG. 20 showing a circuit structure of a memory cell array of a nonvolatile memory in one embodiment of the present invention, memory cells MCᵢⱼ (i=1, 2, 3, . . . , m; and j=1, 2, 3, . . . , n) are arranged at intersections of first connection conductors in parallel (hereafter, referred to as “word lines”) WLᵢ (I=1, 2, 3, . . . , m) and second connection conductors in parallel (hereafter, referred to as “bit lines”) BLⱼ (j=1, 2, 3, . . . , n) intersecting the word lines WLᵢ. Each of the memory cells includes a series connection of a selector element SE and a phase change resistance element VR.

In the drawing, the selector element SE in a memory cell MCᵢⱼ has its one end connected with a word line WLᵢ and the phase change resistance element VR in the memory cell MCᵢⱼ has its one end connected with a bit line BLⱼ. However, since selection of the memory cell MCᵢⱼ depends on the voltages to be applied to the word lines WLᵢ and bit lines BLⱼ, the selector element SE in the memory cell MCᵢⱼ may have its one end connected with the bit line BLⱼ with the phase change resistance element VR in the memory cell MCᵢⱼ having its one end connected with a word line WLᵢ.

A recording operation of the nonvolatile memory is carried out as follows. When, for example, a memory cell MC₁₁ is to be rewritten, a voltage Vₕ is applied to a first word line WL₁ with a voltage V₁ being applied to the other word lines WLᵢ and a voltage V₁ is applied to a first bit line BL₁ with a voltage V₁ being applied to the other bit lines BLⱼ, so that an electric current flows in the phase change resistance element VR of the memory cell MC₁, to thereby store information. Here, voltage Vₕ is higher than voltage V₁. Selector elements SE are indispensable elements which serve to prevent erroneous writing in non-selected memory cells during a rewriting operation. Apparently, the voltage Vₕ should be lower than the breakdown voltage of the selector elements.

In a reading operation of the nonvolatile memory, when information in a memory cell MC₁₁ is to be read out, for example, a voltage Vₘ is applied to the first word line WL₁ with a voltage V₁ being applied to the other word lines WLᵢ and a voltage V₁ is applied to the first bit line BL₁, so that information is read out in terms of the intensity of an electric current flowing in the bit line BL₁.

The above description on the writing and reading operations has been made on an assumption that the memory matrix is formed with a first layer, i.e., with a single layer. By making use of multiple layers, the storage capacity will be increased to advantage.

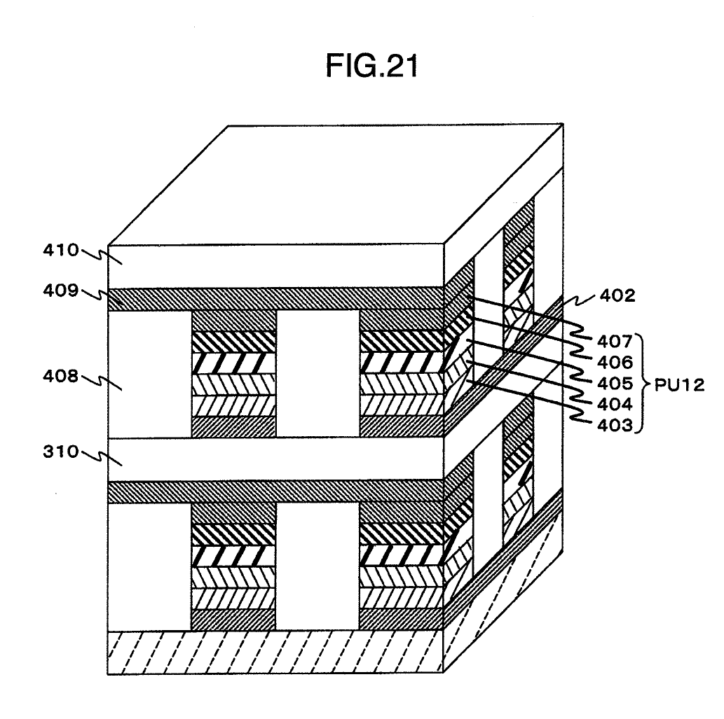

For example, according to a modification of Embodiment 1, a memory matrix in a two-layer structure as shown in FIG. 21 is attained as follows. Namely, on the structure such as shown in FIG. 18, that is, on the insulating material 310 (229), first metal connection conductor layers 402 serving as word lines of the memory matrix in a second level layer, multi-layer films PU12 of the memory matrix in the second level layer, third metal connection conductor layers 409 serving as bit lines of the memory matrix in the second level layer, and an insulating material 408 and an insulating material 409 are formed, in a manner similar to that described in connection with Embodiment 1 with reference to FIGS. 5 to 8. Each of the multi-layer films PU12 includes first and second poly-silicon layers 403 and 404 in the second level layer, semiconductor layers 405 in the second level layer, nonvolatile recording material layers 406 in the second level layer and second metal connection conductor layers 407 in the second level layer.

In the modification of Embodiment 1 shown in FIG. 21, during annealing of the poly-silicon layers in the second level layer, the nonvolatile recording material layers 214 in the first level layer may be heated at the same time. However, since the layers 214 are covered with the metal connection conductor layers and insulating material, there is no fear that they are deformed or separated.

Furthermore, when the memory matrix is implemented with k layers (k=1, 2, 3, . . . , l), similar manufacturing steps may be employed. It is apparent that, when memory matrix is in a multi-layer structure in which plural memory matrix layers are provided, selection of a layer has to be accomplished for recording and reading the nonvolatile memory. For selection of a layer, when word lines are provided in common to all layers, a layer to be written may be selected by the use of bit lines.

As described above, use of the memory matrix with the multi-layer structure in which plural memory matrix layers (or plural memory matrix planes) are provided leads to an increase of the bit density of memory cells, which makes it possible to manufacture nonvolatile memories at low costs.

### Embodiment 2

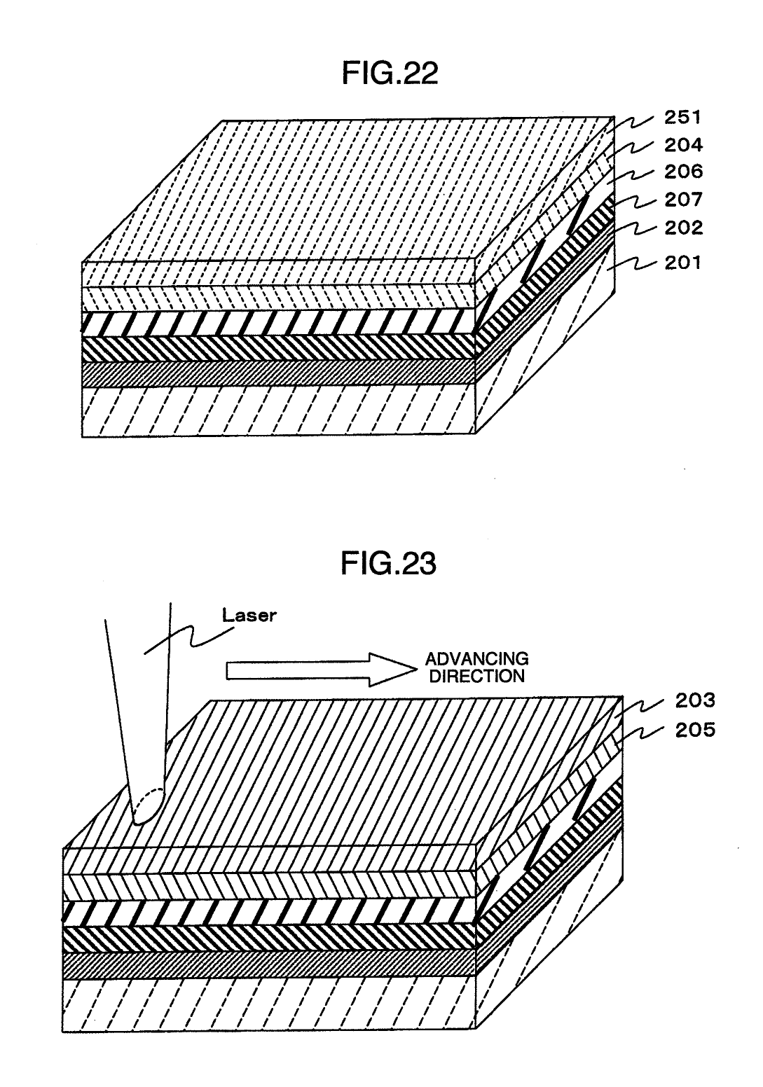

In this embodiment, as shown in FIG. 22, memory cells are formed on a semiconductor substrate 201. The semiconductor substrate 201 is not only for a nonvolatile memory but also for a peripheral circuit to be fabricated therein for operating the memory matrix of the nonvolatile memory. The peripheral circuit may be fabricated by the use of the conventional CMOS technology. The positional relationship between the peripheral circuit and the memory matrix may be similar to that in Embodiment 1.

Referring back to FIG. 22 showing a structure at a step in which, on a semiconductor substrate 201, a first metal connection conductor layer 202, a nonvolatile recording material layer 207, a semiconductor layer 206, a second amorphous silicon layer 204 and a first amorphous silicon layer 251 are formed, in the described order. The first metal connection conductor layer 202 is made of tungsten and is formed by sputtering. More preferably, the layer 202 should be made of, for example, aluminum or copper, because these materials have resistivities lower than that of tungsten to exhibit smaller voltage drops which will permit a higher readout current. Further, an intermetallic compound such as TiN may be formed between the first metal connection conductor layer 202 and the semiconductor substrate 201 to strengthen their adhesion to each other. The nonvolatile recording material layer 207 and the semiconductor layer 206 are formed by sputtering.

The nonvolatile recording material layer 207 is made of, for example, Ge₂Sb₂Te₅ which is suitable for the crystalline-amorphous phase change recording and is 5 to 300 nm thick. More preferably, the layer 207 should be 5 to 20 nm thick to lower its aspect ratio thereby facilitating subsequent steps of dry etching and burying insulating materials. At this step as shown in FIG. 22, the nonvolatile recording material layer 207 may be subjected to laser annealing with the semiconductor layer 206 used as a protective layer. In this case, it is preferable that the laser used to anneal the semiconductor layer 206 should have a long wavelength of not shorter than 460 nm and not longer than 1 μm, but a short wavelength laser of 450 nm or shorter may be used so that the laser light beam is absorbed by the poly-silicon layer and the nonvolatile recording material layer 207 is heated through heat conduction. The laser beam radiation may be continuous or pulsed.

The second amorphous silicon layer 204 is formed by depositing amorphous silicon containing phosphorus or arsenic by LP-CVD. The layer 204 is 50 to 250 nm thick. The first amorphous silicon layer 251 is formed by depositing by LP-CVD an amorphous silicon containing boron, gallium or indium. The layer 251 is 50 to 250 nm thick.

The semiconductor layer 206 should not be too thick and should not be too thin to carry out its intended function. If it is too thick, it will have a too large resistance, though electrically conductive, with the resistance being temperature-dependent to make the temperature margin of the resistance of the nonvolatile recording material layer 207 insufficient. If it is too thin, it will not serve to prevent degradation of the characteristics of the selector element due to the repetitive temperature rise in the nonvolatile recording material layer 207 at a storing/rewriting operation. For the reasons described above, the layer 206 should preferably have a thickness of not smaller than 5 nm and not larger than 200 nm.

The semiconductor layer 206 is made of a material having a Ge content not smaller than 90%, the material being therefore resistant to the rewriting conditions of the nonvolatile recording material layer 207. Alternately, the layer 206 may be made of the same material as that of the semiconductor layer described in connection with Embodiment 1. Although, in this embodiment, the material of the nonvolatile recording material layer 207 is Ge₂Sb₂Te₅ by way of example, another nonvolatile recording material layer made of Ge₃Sb₂Te₆, Ge₅Sb₂Te₈ or Ge—Te may be used instead. Alternately, the layer 207 may be made of a solid electrolyte material suitable for the solid electrolyte memory recording.

FIG. 23 illustrates a step of laser-annealing the second amorphous silicon layer 204 and the first amorphous silicon layer 251 deposited as explained with reference to FIG. 22. By the laser-annealing, the second and first amorphous silicon layers 204 and 251 are crystallized and the dopants are activated, thereby forming a second poly-silicon layer 205 and a first poly-silicon layer 203. In this embodiment, the selector element in each memory cell is a pn diode, so that the junction between the first and second poly-silicon layers 203 and 205 is a pn junction. However, a selector element having another junction such as an np junction, a pin junction or a pi junction may be used to constitute a memory cell.

When the nonvolatile recording material layer 207 is formed under the semiconductor layer 206 and the second and first amorphous silicon layers 204 and 251, annealing of the nonvolatile recording material layer 207 by the use of laser beam radiation at least with the semiconductor layer 206 used as a protective layer significantly decreases the arrangement disorder of atoms in the as-eposited state in the layer 207 so that it is possible to enhance the operation yield of the memory element by 10% or more.

When the poly-silicon layers are annealed, it is possible that the nonvolatile recording material layer 207 underlying the poly-silicon layers through the semiconductor layer 206 may be heated to a temperature considerably higher than its melting point. In this respect, annealing by the use of a short-pulse laser beam having a short wavelength makes it possible to suppress downward thermal diffusion to prevent deformation and separation of the layer 207. When a pulse laser radiation is employed in which the wavelength is 450 nm or shorter and the pulse duration is 100 μsec or shorter, neither deformation nor separation of the layer 207 is observed.

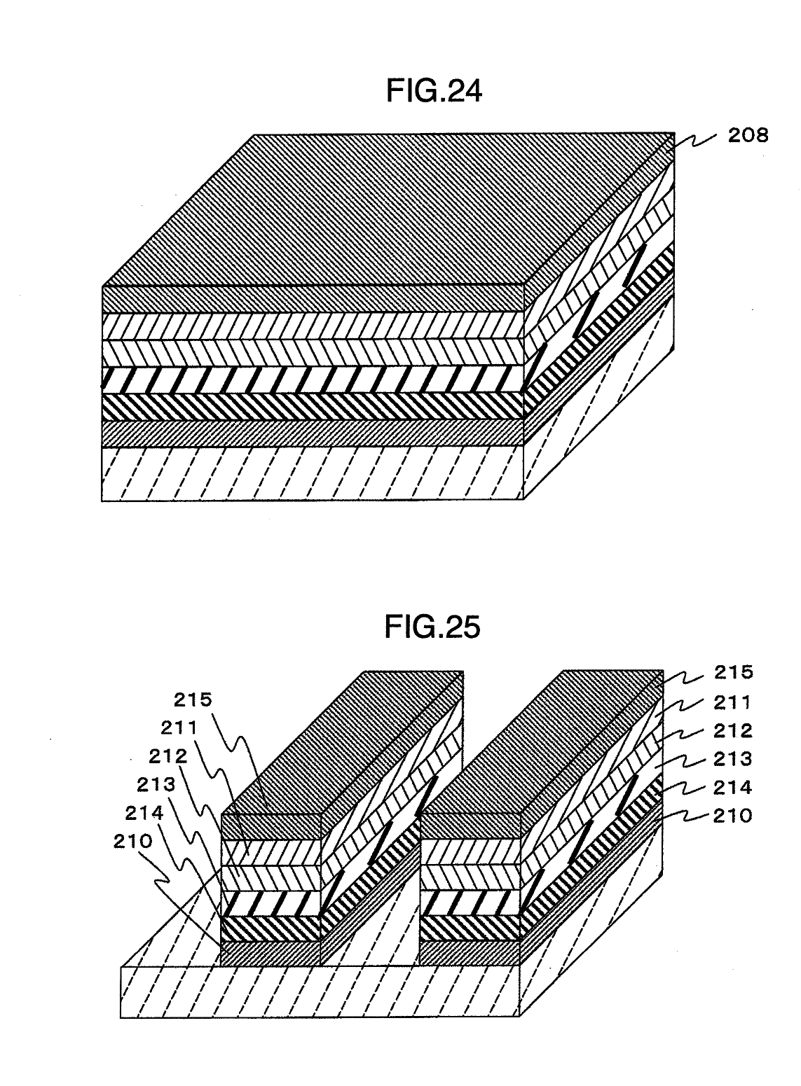

FIG. 24 shows a structure at a step in which, on the poly-silicon layer 203 of the structure shown in FIG. 23, a second metal connection conductor layer 208 is formed by sputtering. The layer 208 is made of tungsten. However, more preferably, it should be made of aluminum or copper having a lower resistivity.

FIG. 25 shows a structure at a step in which known lithography and dry etching techniques are applied, in a manner similar to that described with reference to FIGS. 11 and 12, to the structure having the second metal connection conductor layer 208 as an uppermost layer as shown in FIG. 24, thereby patterning the second metal connection conductor layer 208, the first poly-silicon layer 203, the second poly-silicon layer 205, the semiconductor layer 206, the nonvolatile recording material layer 207 and the first metal connection conductor layer 202.

The multi-layer films each including a first metal connection conductor layer 210, a first poly-silicon layer 211, a second poly-silicon layer 212, a semiconductor layer 213, a nonvolatile recording material layer 214 and a second metal connection conductor layers 215 thus obtained are in a longitudinally striped pattern identical with that of word lines in a memory matrix and extend in parallel with each other. Although the first metal connection conductor layers 210 serving as word lines in a memory matrix are electrically connected with the semiconductor substrate 201 for reading and writing the nonvolatile memory, illustration of such electrical connection is omitted.

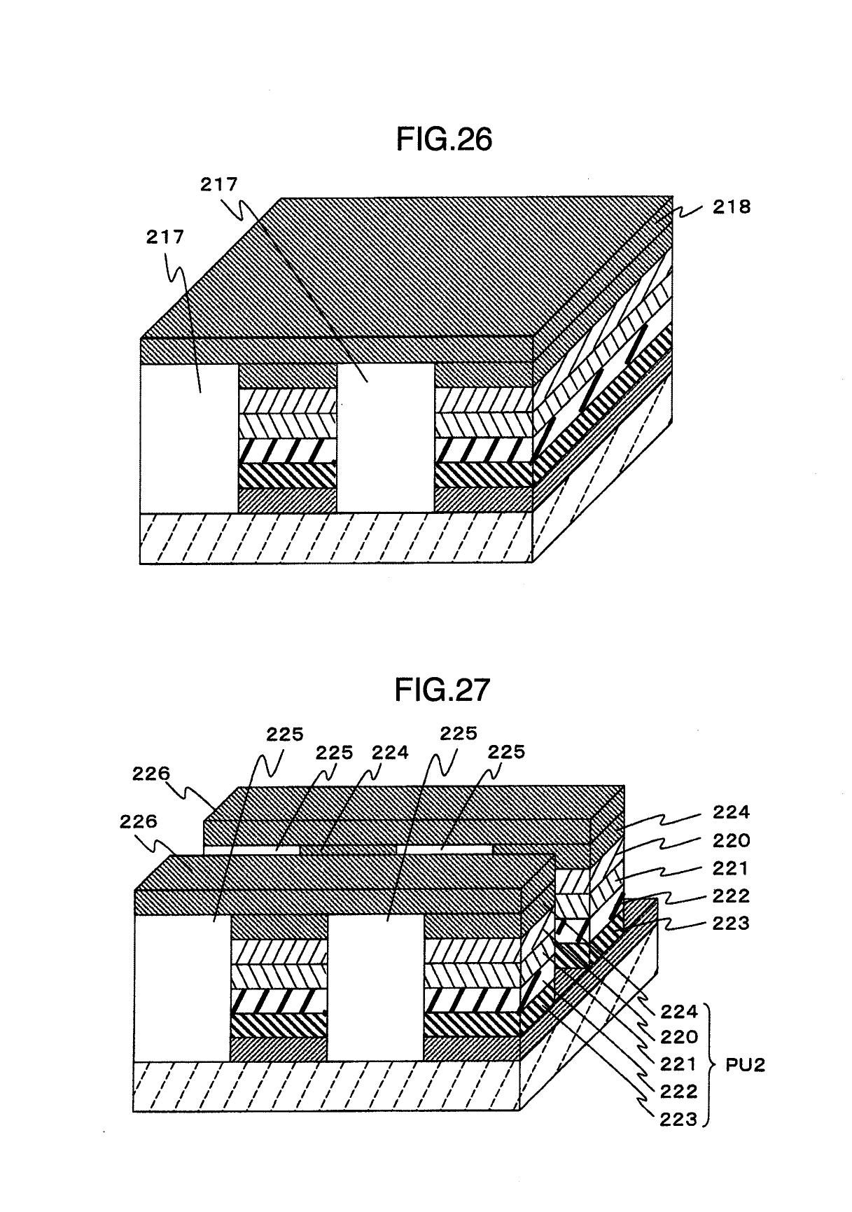

FIG. 26 shows a structure at a step in which, on the patterned structure shown in FIG. 25, an electrically insulating material 217 is formed by HDP-CVD and is then leveled by CMP. Thereafter, a third metal connection conductor layer 218 is formed by the known sputtering technique. The layer 218 is made of tungsten, but more preferably, it may be made of aluminum or copper having a lower resistivity.

FIG. 27 shows a structure at a step in which known lithography and dry etching techniques are applied to the structure shown in FIG. 26, thereby patterning the third metal connection conductor layer 218, the second metal connection conductor layer 215, the nonvolatile recording material layer 214, the semiconductor layer 213, the second poly-silicon layer 212, the first poly-silicon layer 211 and the insulating material 217. At this time, it is necessary to leave the first metal connection conductor layers 210 as they are, the first metal connection conductor layers 210 serving as word lines in the memory matrix so that selection of memory cells is possible.

A nonvolatile recording material layer 223, a semiconductor layer 222, a second poly-silicon layer 221, a first poly-silicon layer 220 and a second metal connection conductor layer 224 thus obtained constitute a multi-layer film PU2 which is pillar-shaped. The pattern of third metal connection conductor layers 226 is for bit lines of a memory matrix and is laterally striped, extending in parallel with adjacent pattern of the third metal connection conductor layers 226 (bit lines). The pattern of the third metal connection conductor layers 226 intersects the pattern of the first metal connection conductor layers 210. Furthermore, although the third metal connection conductor layers 226 as bit lines are electrically connected with the semiconductor substrate 201 for reading and writing the nonvolatile memory, illustration of such electrical connection is omitted.

At a step in which the first poly-silicon layer is formed, by optimizing the semiconductor layer, the first poly-silicon layer and the nonvolatile recording material layer may be simultaneously subjected to laser annealing by the use of continuous or pulsed laser beam having a wavelength of not shorter than 350 nm and not longer than 450 nm. In this case, it is preferable that the semiconductor layer be made of a Si—Ge mixture material.

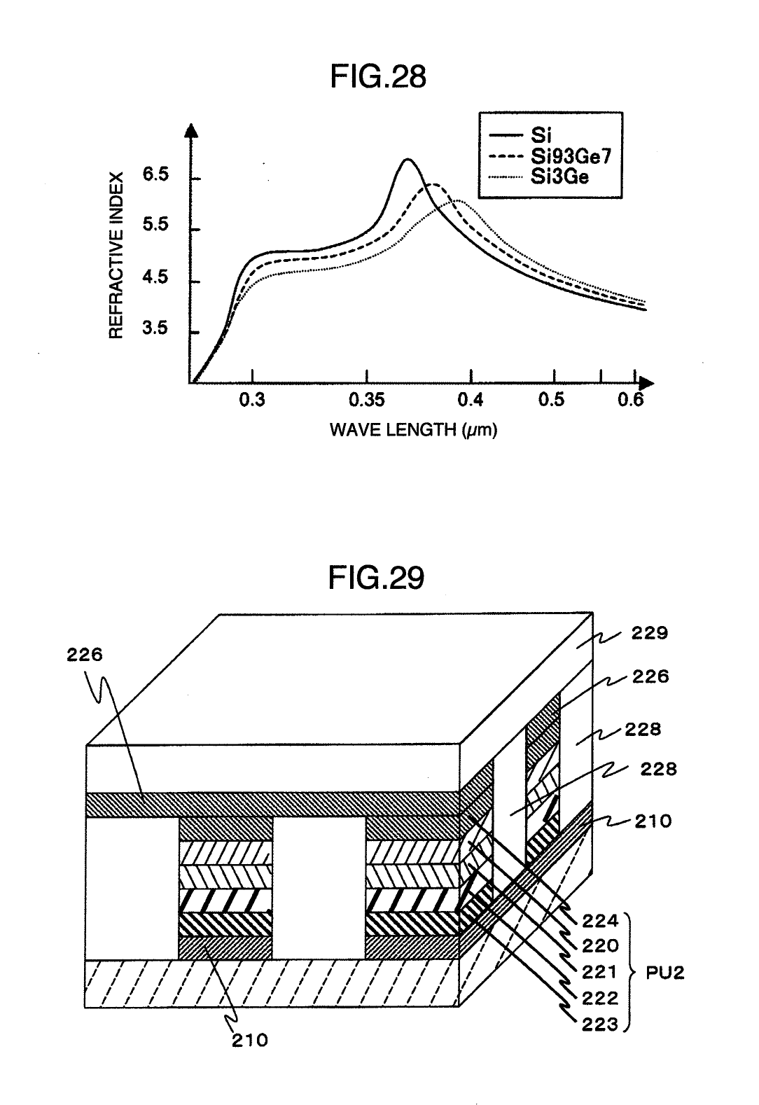

Si—Ge mixture materials have refractive index and extinction coefficient which are wavelength-dependent as shown in FIG. 28. Therefore, the annealing of the poly-silicon layer and the nonvolatile recording material layer may be achieved in the following manner. Namely, the nonvolatile recording material layer is annealed with a long wavelength laser beam having a wavelength of not shorter than 460 nm and not longer than 1 μm which passes through the poly-silicon layer and thereafter the poly-silicon layer is annealed with a short wavelength laser beam having a wavelength of 350 nm or shorter. More preferably, the semiconductor layer should be made of a Si—Ge material containing not smaller than 77 atomic % and not larger than 94 atomic % of Si and should have a thickness of not smaller than 5 nm and not larger than 200 nm, so that both the poly-silicon layer and the nonvolatile recording material layer are most satisfactorily annealed.

FIG. 29 shows a structure at a step in which, on the patterned structure shown in FIG. 27, an electrically insulating material 228 is formed by HDP-CVD and is then leveled by CMP. Thereafter, an insulating material 229 is formed on the resulting structure by a known sputtering technique.

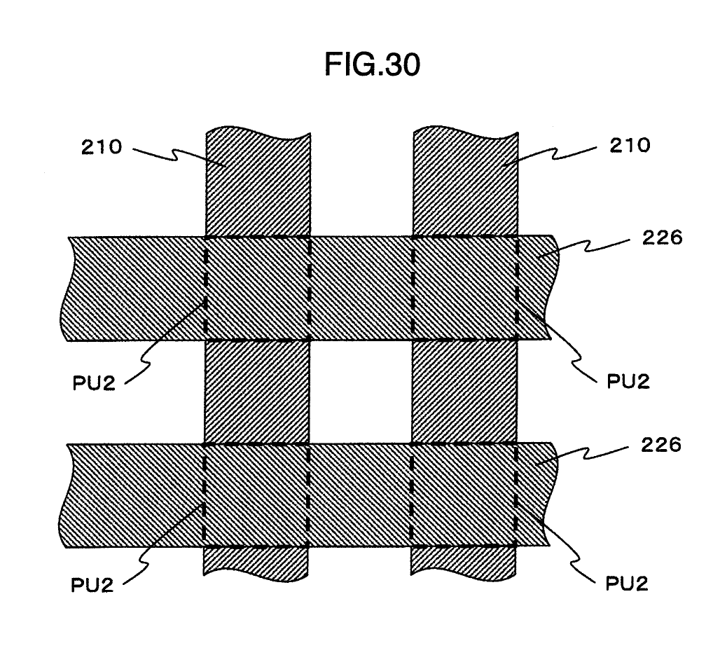

FIG. 30 is a plan view of the structure manufactured according to the steps described with reference to FIGS. 22 to 27 and FIG. 29. The first metal connection conductor layers 210 serving as the word lines in the memory cells intersect the third metal connection conductor layers 226 serving as the bit lines in the memory cells, and the multi-layer films PU2 are arranged at the intersections. The materials of the respective layers may be similar to those in Embodiment 1. Furthermore, as explained with reference to Embodiment 1, the memory matrix may be of the multi-layer structure in which plural memory matrix layers (planes) are provided.

The principle of the operation of the memory matrix including memory cells using the nonvolatile memory according to this embodiment is similar to that according to Embodiment 1.

### Embodiment 3

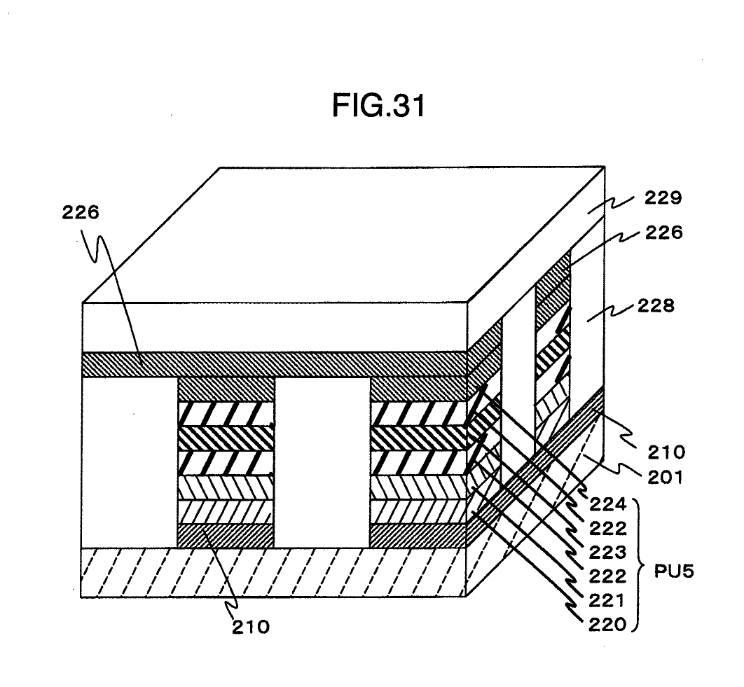

FIG. 31 is a perspective view of a semiconductor memory device, in which, on a semiconductor substrate 201, first metal connection conductor layers 210 serving as word lines in a memory matrix, pillar-shaped multi-layer films PU 5, third metal connection conductor layers 226 serving as bit lines in the memory matrix and insulating materials 229 and 228 are formed in a manner similar to that described in connection with Embodiment 1 with reference to FIGS. 5 to 18. Each of the multi-layer films PU 5 includes first and second poly-silicon layers 220 and 221, a semiconductor layer 222, a nonvolatile recording material layer 223, another semiconductor layer 222 and a second metal connection conductor layer 224.

The provision of the semiconductor layers leads to prevention of the degradation of the nonvolatile recording material layers stemming from the heat cycles at repetitive writing on the nonvolatile recording material layer and to the effect that the maximum number of times of rewriting is increased at least to five times as large as that without the semiconductor layers. The total thickness of the semiconductor layers at different levels may be equal to the thickness of the semiconductor layer employed in Embodiment 1. The materials of the respective layers may be the same as those in Embodiment 1. Furthermore, as in the modification of Embodiment 1, a memory matrix may be implemented in a multi-layer structure in which plural memory matrix layers (planes) are provided.

In this embodiment, the additional semiconductor layers are provided under the second metal connection conductor layers, which makes it possible to laser-anneal, after formation of the additional semiconductor layers, the nonvolatile recording material layers with the additional semiconductor layers under the second metal connection conductor layers used as protective layers.

The principle of the operation of the memory matrix including the memory cells in the nonvolatile memory according to this embodiment is similar to that according to Embodiment 1. Further, the positional relationship between the peripheral circuit and the memory matrix may be similar to that in Embodiment 1.

### Embodiment 4

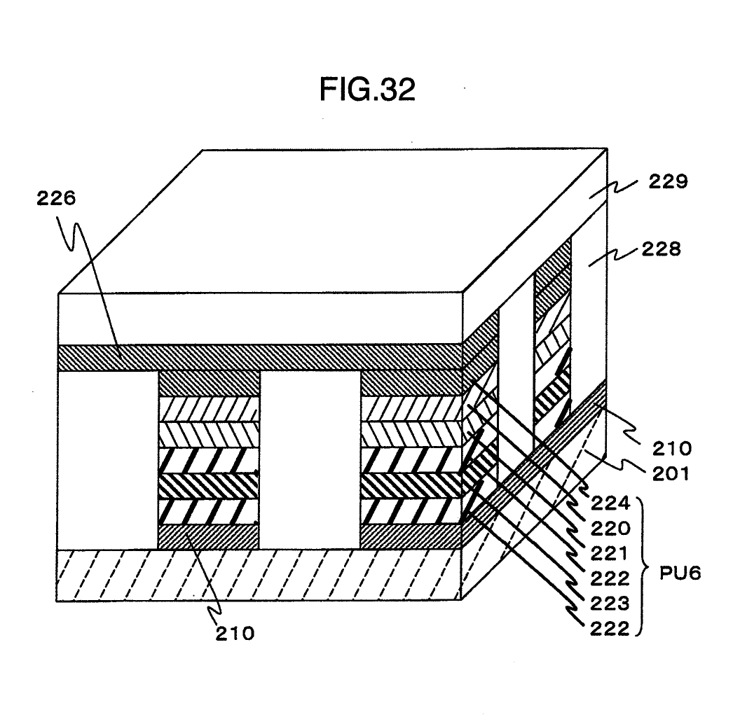

FIG. 32 is a perspective view of a semiconductor memory device, in which, on a semiconductor substrate 201, first metal connection conductor layers 210 serving as word lines in a memory matrix, pillar-shaped multi-layer films PU 6, third metal connection conductor layers 226 serving as bit lines in the memory matrix and insulating materials 228 and 229 are formed in a manner similar to that described in connection with Embodiment 1 with reference to FIGS. 5 to 18. Each of the multi-layer films PU 6 includes a semiconductor layer 222, a nonvolatile recording material layer 223, another semiconductor layer 222, a second poly-silicon layer 221, a first poly-silicon layer 220 and a second metal connection conductor layer 224.

The provision of the semiconductor layers leads to prevention of the degradation of the nonvolatile recording material layers stemming from the heat cycles at repetitive writing on the nonvolatile recording material layer and to the effect that the maximum number of times of rewriting is increased at least to five times as large as that without the semiconductor layers. The total thickness of the semiconductor layers at different levels may be equal to that in Embodiment 1. The materials of the respective layers may be the same as those in Embodiment 1. Furthermore, as in the modification of Embodiment 1, a memory matrix may be implemented in a multi-layer structure in which plural memory matrix layers (planes) are provided.

The principle of operation of the memory matrix including memory cells in the nonvolatile memory according to this embodiment is similar to that according to Embodiment 1. Furthermore, the positional relationship between the peripheral circuit and the memory matrix may be similar to that in Embodiment 1.

According to the various embodiments having been described above, the semiconductor layer is provided between the poly-silicon diode and the nonvolatile recording material layer, the semiconductor layer containing an element identical with that contained in the nonvolatile recording material layer. Thereby, it is possible to suppress diffusion, into the nonvolatile recording material layer, of an impurity contained in the poly-silicon diode due to heat generated in rewriting operations. Furthermore, the semiconductor layer contains an element identical with that contained in the nonvolatile recording material layer. Therefore, even when the element in the semiconductor layer diffuses into the nonvolatile recording material layer, there will be little influence exerted on the rewriting conditions. Consequently, the nonvolatile memories according to the embodiments have stabilized rewriting conditions and/or an increased maximum number of times of rewriting as compared to the conventional memories.

Although the above embodiments have been described with respect to phase change memories, the nonvolatile recording material layer may be of any of the known materials for the nonvolatile recording such as phase change materials, solid electrolyte materials and magnetic materials, without departing from the technical concept of the present invention. The semiconductor layer to be provided should contain an element identical with that contained in the nonvolatile recording material employed to obtain functional effects similar to those described above.

It should be further understood by those skilled in the art that although the foregoing description has been made on embodiments of the invention, the invention is not limited thereto and various changes and modifications may be made without departing from the spirit of the invention and the scope of the appended claims.

1. A nonvolatile semiconductor memory device comprising:
a first electrode;
a second electrode;
a nonvolatile recording material layer and a selector element both formed between said first and second electrodes; and
a semiconductor layer formed between said nonvolatile recording material layer and said selector element, said semiconductor layer containing an element identical with that contained in said nonvolatile recording material layer.

2. A nonvolatile semiconductor memory device according to claim 1, wherein:
said semiconductor layer is formed on said selector element; and
said nonvolatile recording material layer is formed on said semiconductor layer.

3. A nonvolatile semiconductor memory device according to claim 1, wherein:
said semiconductor layer is formed on said nonvolatile recording material layer; and
said selector element is formed on said semiconductor layer.

4. A nonvolatile semiconductor memory device according to claim 1, wherein said nonvolatile recording material layer contains at least one of chalcogen elements.

5. A nonvolatile semiconductor memory device according to claim 1, wherein said semiconductor layer contains at least 40 atomic % of Ge.

6. A nonvolatile semiconductor memory device according to claim 5, wherein said semiconductor layer contains at least 90 atomic % of Ge.

7. A nonvolatile semiconductor memory device according to claim 1, wherein said semiconductor layer is made of a mixture of Ge and Si.

8. A nonvolatile semiconductor memory device according to claim 1, wherein said semiconductor layer is made of InSb or GaSb.

9. A nonvolatile semiconductor memory device according to claim 1, wherein said semiconductor layer has a thickness of not smaller than 5 nm and not larger than 200 nm.

10. A nonvolatile semiconductor memory device according to claim 1, wherein said selector element is a diode.

11. A nonvolatile semiconductor memory device according to claim 10, wherein said diode is a pin polycrystalline silicon diode.

12. A nonvolatile semiconductor memory device according to claim 1, wherein:
the device includes a memory cell having said nonvolatile recording material layer and said selector element; and
said memory cell is a phase-change type memory cell.
